(19) United States
(12) Patent Application Publication
(10) Pub. No.: US 2026/0344496 A1
(43) Pub. Date: Oct. 29, 2026

(54) SEMICONDUCTOR DIE WITH TRENCH STRUCTURES

(71) Applicant: Texas Instruments Incorporated, Dallas, TX (US)

(72) Inventors: Guangxu Li, Allen, TX (US); Rajen Manicon Murugan, Dallas, TX (US); Alfred Griffin, Dallas, TX (US)

(21) Appl. No.: 19/193,485

(22) Filed: Apr. 29, 2025

(51) Int. Cl. H10W 72/90; H10W 70/40; H10W 72/00; H10W 72/50; H10W 72/59; H10W 74/10; H10W 90/00

(52) U.S. Cl. CPC H10W 72/90; H10W 72/075; H10W 72/50; H10W 70/40; H10W 72/07502; H10W 72/536; H10W 72/59; H10W 72/923; H10W 72/934; H10W 72/952; H10W 74/111; H10W 90/756

(57) ABSTRACT

A semiconductor die comprises a semiconductor substrate. The semiconductor die also comprises a back-end-of-line (BEOL) layer on the semiconductor substrate. The BEOL layer comprises a dielectric layer on a top surface. The semiconductor die further comprises a contact pad on the dielectric layer. The dielectric layer on the top surface of the BEOL layer comprises a trench, which locates along a periphery of the contact pad. The trench can alleviate stress during wire bonding process and reliability test to improve reliability of the semiconductor die.

### FIELD

The present disclosure relates generally to wire bond packages, and more particularly to wire bond packages employing semiconductor dies with trench structures for enhanced reliability.

### BACKGROUND

Wire bonding is a frequently used method for connecting a semiconductor die to a package substrate, such as a lead frame. One end of a bond wire is bonded to a contact pad of the semiconductor die and the other end of the bond wire is bonded to the package substrate. There are two main classes of wire bonding: ball bonding and stitch bonding. Each typically uses some combination of heat, pressure, and ultrasonic energy to form a bond. A ball bond is most often used to form a connection between the bond wire and the semiconductor die. A stitch bond is most often used to connect the bond wire to the package substrate. Bond wires are typically made from copper or gold. A diameter of the bond wire may be as small as 15 μm. A tool used to perform wire bonding dispenses the bond wire from a needle like device called a capillary. In forming a ball bond, the capillary melts a small portion of wire near its tip to form a molten ball. The molten ball is then pressed against a contact pad on the semiconductor die by the capillary, which is then pulled away to form the ball bond on the contact pad. As the capillary is moved away from the contact pad, it dispenses wire, which remains connected to the ball bond. The capillary then moves to a position over the package substrate where it forms another bond, usually a stitch bond, to electrically connect the semiconductor die to the package substrate.

### SUMMARY

This summary is provided to introduce a selection of disclosed concepts in a simplified form that are further described below in the detailed description including the drawings provided. This summary is not intended to limit the scope of the claimed subject matter.

Disclosed aspects include a semiconductor die. The semiconductor die comprises a semiconductor substrate. The semiconductor die also comprises a back-end-of-line (BEOL) layer on the semiconductor substrate. The BEOL layer comprises a dielectric layer on a top surface. The semiconductor die further comprises a contact pad on the dielectric layer. The dielectric layer comprises a trench and the trench locates along a periphery of the contact pad.

Disclosed aspects include a semiconductor package. The semiconductor package comprises a package substrate. The semiconductor package also comprises a semiconductor die coupled to the package substrate. The semiconductor die comprises a semiconductor substrate. The semiconductor die also comprises a back-end-of-line (BEOL) layer on the semiconductor substrate. The BEOL layer comprises a dielectric layer on a top surface. The semiconductor die further comprises a contact pad on the dielectric layer. The dielectric layer comprises a trench and the trench locates along a periphery of the contact pad. The semiconductor package also comprises a bond wire coupled to the contact pad and the package substrate. The semiconductor package further comprises a mold compound covering the package substrate, the semiconductor die, and the bond wire.

Disclosed aspects include a method of forming a semiconductor package. The method comprises attaching a semiconductor die to a package substrate. The semiconductor die comprises a semiconductor substrate. The semiconductor die also comprises a back-end-of-line (BEOL) layer on the semiconductor substrate. The BEOL layer comprises a dielectric layer on a top surface. The semiconductor die further comprises a contact pad on the dielectric layer. The dielectric layer comprises a trench and the trench locates along a periphery of the contact pad. The method also comprises attaching a bond wire to the contact pad and the package substrate. The method further comprises covering the semiconductor die, the package substrate, and the bond wire with a mold compound.

### BRIEF DESCRIPTION OF THE DRAWINGS

Reference will now be made to the accompanying drawings, which are not necessarily drawn to scale, wherein:

FIG. 1 is a 3D view of an example semiconductor package comprising a semiconductor die with trench structures wire bonded to a package substrate in accordance with certain aspects of present disclosure;

FIG. 2A is a zoomed in cross-section view of a wire bond of the semiconductor package of FIG. 1;

FIG. 2B is a zoomed in cross-section view of a portion of the semiconductor die adjacent the wire bond of FIG. 2A;

FIG. 3 illustrates a fabrication process for an example semiconductor package comprising a semiconductor die with trench structures wire bonded to a package substrate in accordance with certain aspects of present disclosure;

FIG. 4 a 3D view of an example device including a semiconductor package comprising a semiconductor die with trench structures wire bonded to a package substrate in accordance with certain aspects of present disclosure;

FIG. 5A illustrates simulation results of stresses on a top surface of a semiconductor die with and without trench structures under a shear load; and

FIG. 5B illustrates simulation results of stresses on a top surface of a semiconductor die with and without trench structures under a thermal cycle test.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including,” “includes,” “having,” “has,” “with,” or variants thereof are intended to be inclusive in a manner similar to the term “comprising,” and thus should be interpreted to mean “including, but not limited to.”

Unless otherwise stated, “about,” “approximately,” or “substantially” preceding a value means +/−10 percent of the stated value. One or more structures, features, aspects, components, etc., may be referred to herein as first, second, third, etc., such as first and second terminals, first, second, and third dies, etc., for ease of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

Wire bonding can result in damage to a semiconductor die when a bond wire is attached to a contact pad on the semiconductor die. This is because wire bonding generally includes application of heat, pressure, and ultrasonic energy, which results in mechanical stress imposed onto the contact pad that is transmitted to structures underneath the contact pad including metal and dielectric layers. The mechanical stress can potentially cause damage to those underlying structures. Such damage can quickly propagate through the metal and dielectric layers during assembly process or reliability test to cause more severe failure of the semiconductor die. One possible solution is to make the metal and dielectric layers mechanically stronger to become more resistant to damage under mechanical stress of wire bonding, while another possible solution is to reduce pressure and ultrasonic energy applied during wire bonding process.

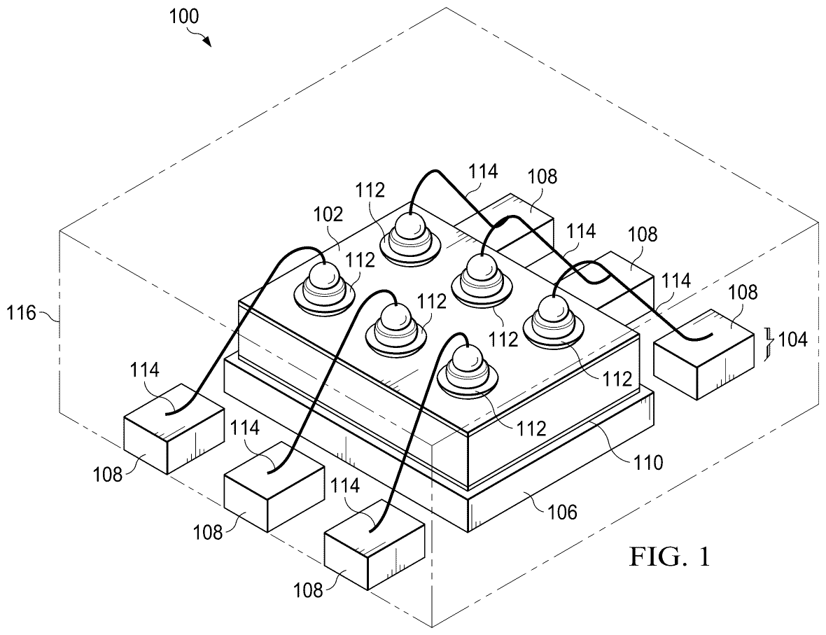

Disclosed aspects include a semiconductor package comprising a semiconductor die with trench structures wire bonded to a package substrate. FIG. 1 is a 3D view of a semiconductor package 100 comprising a semiconductor die with trench structures wire bonded to a package substrate in accordance with certain aspects of present disclosure. The semiconductor package 100 comprises a semiconductor die 102. The semiconductor package 100 also comprises a package substrate. The package substrate is shown as a lead frame 104 in FIG. 1, but the package substrate may comprise any other suitable types of substrates. The lead frame 104 comprises a die attach pad 106 and a plurality of leads 108. The semiconductor die 102 is coupled to the die attach pad 106 via a die attach material 110. The semiconductor die 102 comprises a plurality of contact pads 112. The plurality of contact pads 112 may comprise copper (Cu). The semiconductor package 100 also comprises a plurality of bond wires 114. The plurality of bond wires 114 may comprise Cu or gold. The plurality of bond wires 114 couples the plurality of contact pads 112 to the plurality of leads 108. The semiconductor package 100 further comprises a mold compound 116 covering the semiconductor die 102, the lead frame 104, and the plurality of bond wires 114.

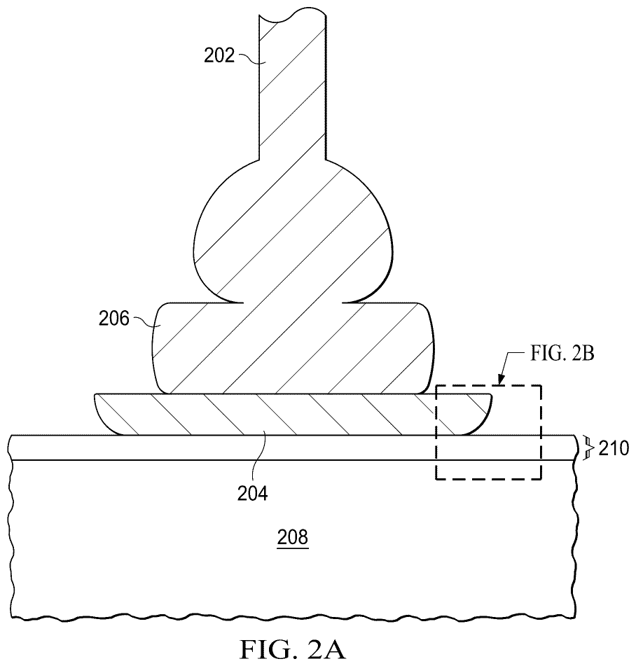

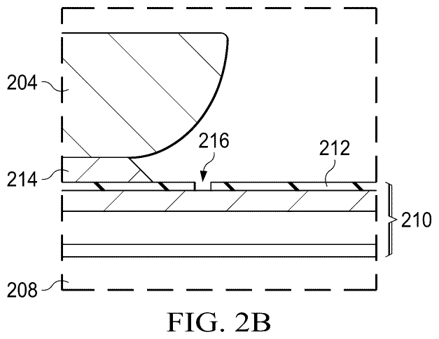

FIG. 2A is a zoomed in cross-section view of a wire bond of the semiconductor package 100 of FIG. 1. The wire bond comprises a bond wire 202 of the plurality of bond wires 114. The bond wire 202 couples to a contact pad 204 of the plurality of contact pads 112 via a bond 206. The bond 206 may comprise a ball bond. The semiconductor die 102 comprises a semiconductor substrate 208 and a back-end-of-line (BEOL) layer 210 on the semiconductor substrate 208. The semiconductor substrate 208 may comprise silicon (Si). The BEOL layer 210 may comprise a plurality of metal layers and dielectric layers. FIG. 2B is a zoomed in cross-section view of a portion of the semiconductor die 102 adjacent the wire bond of FIG. 2A. The portion of the semiconductor die 102 comprises a portion of the contact pad 204, a portion of the BEOL layer 210, and a portion of the semiconductor substrate 208. A dielectric layer 212 on a top surface of the BEOL layer 210 may comprise silicon dioxide (SiO₂). The contact pad 204 is on the dielectric layer 212. The portion of the semiconductor die 102 also comprises a titanium tungsten (TiW) layer 214 between the contact pad 204 and the dielectric layer 212. The portion of the semiconductor die 102 further comprises a trench 216 in the dielectric layer 212 and along a periphery of the contact pad 204. The trench 216 may have a width less than 10 μm. A distance between the trench 216 and a bottom surface of the contact pad 204 may be less than 10 μm. A depth of the trench 216 may be same as a thickness of the dielectric layer 212 and may be about 0.1 μm. The trench 216 may fully surround the contact pad 204 on the top surface of the BEOL layer 210. The trench 216 may comprise a circular shape or any other suitable shapes. The trench 216 can alleviate stress in the BEOL layer 210 during wire bonding process and reliability test, such as thermal cycle test, to improve reliability of the semiconductor package 100.

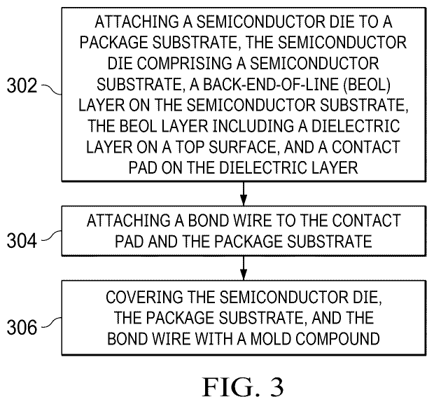

FIG. 3 illustrates a fabrication process for a semiconductor package comprising a semiconductor die with trench structures wire bonded to a package substrate in accordance with certain aspects of present disclosure. Step 302 comprises attaching a semiconductor die to a package substrate. The package substrate may comprise a lead frame. The lead frame comprises a die attach pad and a lead. The semiconductor die is attached to the die attach pad of the lead frame via a die attach material. The semiconductor die comprises a contact pad. The contact pad may comprise Cu. The semiconductor die also comprises a semiconductor substrate and a BEOL layer on the semiconductor substrate. The semiconductor substrate may comprise Si. The BEOL layer may comprise a plurality of metal layers and dielectric layers. A dielectric layer on a top surface of the BEOL layer may comprise SiO₂. The contact pad is on the dielectric layer. The semiconductor die also comprises a TiW layer between the contact pad and the dielectric layer. The semiconductor die further comprises a trench in the dielectric layer and along a periphery of the contact pad. The trench may be formed by a laser grooving process or an etching process. The trench may have a width less than 10 μm. A distance between the trench and a bottom surface of the contact pad may be less than 10 μm. A depth of the trench may be same as a thickness of the dielectric layer and may be about 0.1 μm. The trench may fully surround the contact pad on the top surface of the BEOL layer and may comprise any suitable shapes. The trench can alleviate stress in the BEOL layer during wire bonding process and reliability test, such as thermal cycle test, to improve reliability of the semiconductor package.

Step 304 comprises attaching a bond wire to the contact pad and the package substrate. The bond wire may comprise Cu or gold. The bond wire may form a ball bond on the contact pad and a stitch bond on the lead.

Step 306 comprises covering the semiconductor die, the package substrate, and the bond wire with a mold compound.

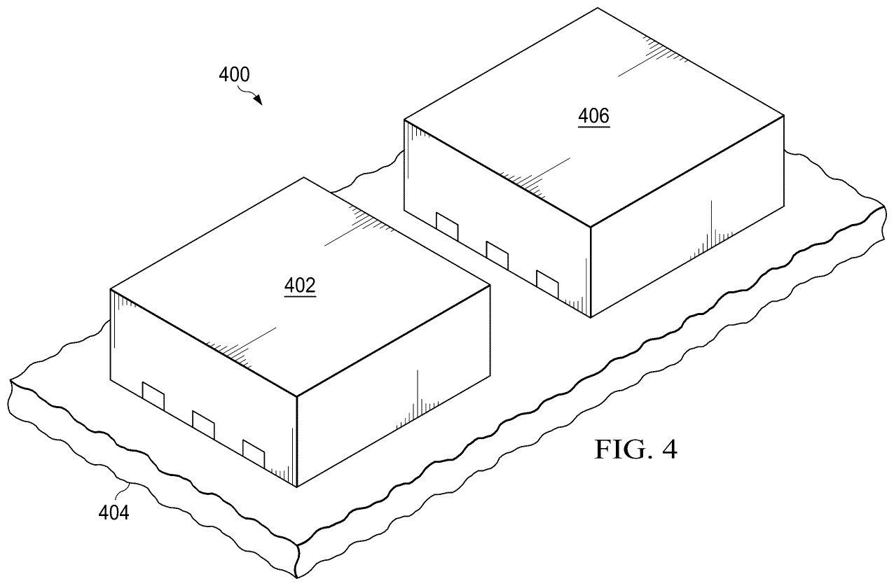

FIG. 4 is a 3D view of a device 400 including a semiconductor package 402 comprising a semiconductor die with trench structures wire bonded to a package substrate in accordance with certain aspects of present disclosure. The device 400 also comprises a printed circuit board (PCB) 404. The semiconductor package 402 is mounted on the PCB 404. The semiconductor package 402 is similar to the semiconductor package 100. The device 400 further comprises another semiconductor package 406 mounted on the PCB 404. The semiconductor packages 402 and 406 operate together to perform functions of the device 400.

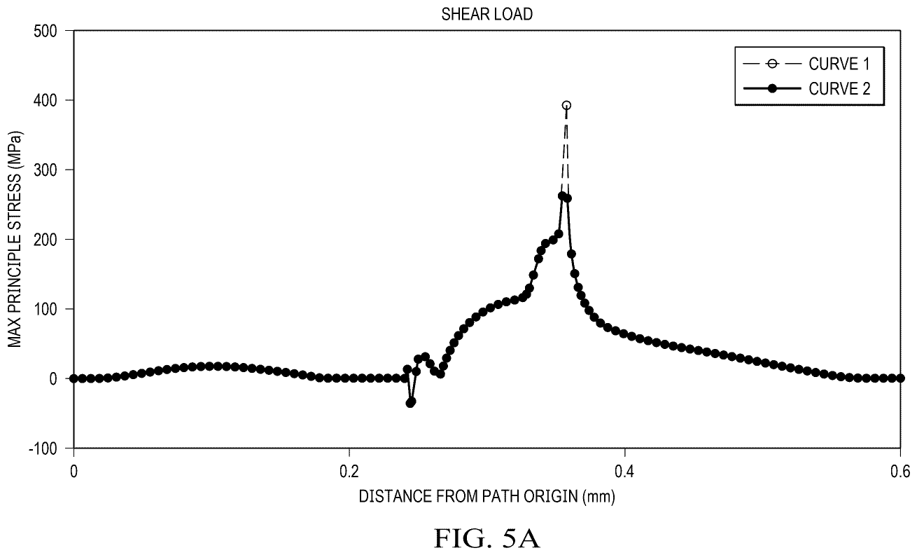

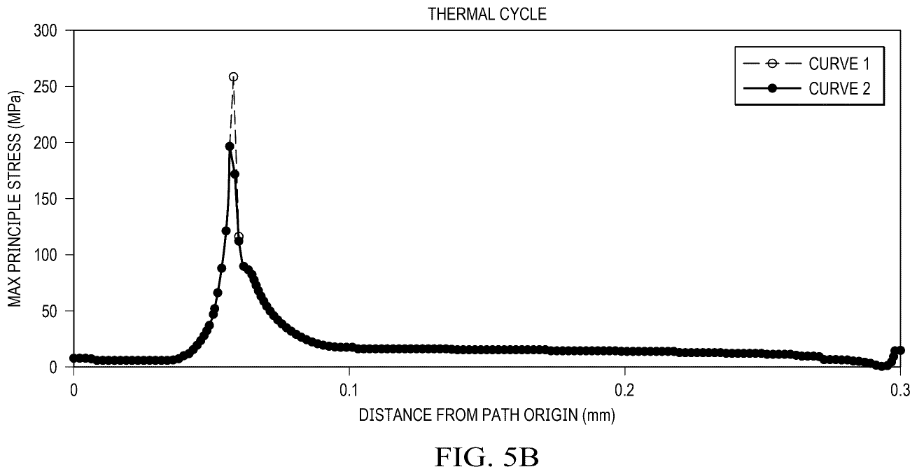

FIG. 5A illustrates simulation results of stresses on a top surface of a semiconductor die with and without trench structures under a shear load. Curve 1 represents a semiconductor die without trench structures. Curve 2 represents a semiconductor die with trench structures similar to the semiconductor die 102. A maximum stress for curve 2 is smaller than a maximum stress for curve 1. Thus, the trench structures can alleviate stress during wire bonding process to improve reliability of the semiconductor die.

FIG. 5B illustrates simulation results of stresses on a top surface of a semiconductor die with and without trench structures under a thermal cycle test. Curve 1 represents a semiconductor die without trench structures. Curve 2 represents a semiconductor die with trench structures similar to the semiconductor die 102. A maximum stress for curve 2 is smaller than a maximum stress for curve 1. Thus, the trench structures can alleviate stress during thermal cycle test to improve reliability of the semiconductor die.

Those skilled in the art to which this disclosure relates will appreciate that many variations of disclosed aspects are possible within the scope of the claimed invention, and further additions, deletions, substitutions, and modifications may be made to the above-described aspects without departing from the scope of this disclosure.

What is claimed is:

1. A semiconductor die, comprising:
a semiconductor substrate;
a back-end-of-line (BEOL) layer on the semiconductor substrate, the BEOL layer including a dielectric layer on a top surface; and
a contact pad on the dielectric layer, wherein the dielectric layer comprises a trench and the trench locates along a periphery of the contact pad.

2. The semiconductor die of claim 1, wherein the dielectric layer comprises silicon dioxide.

3. The semiconductor die of claim 1, wherein a distance between the trench and a bottom surface of the contact pad is less than 10 μm.

4. The semiconductor die of claim 1, wherein a width of the trench is less than 10 μm.

5. The semiconductor die of claim 1, wherein the trench fully surrounds the contact pad on the top surface of the BEOL layer.

6. The semiconductor die of claim 1, further comprising a titanium tungsten layer between the contact pad and the dielectric layer.

7. The semiconductor die of claim 1, wherein a bond wire is coupled to the contact pad.

8. A semiconductor package, comprising:
a package substrate;
a semiconductor die coupled to the package substrate, the semiconductor die comprising a semiconductor substrate, a back-end-of-line (BEOL) layer on the semiconductor substrate, the BEOL layer including a dielectric layer on a top surface, and a contact pad on the dielectric layer, wherein the dielectric layer comprises a trench and the trench locates along a periphery of the contact pad;
a bond wire coupled to the contact pad and the package substrate; and
a mold compound covering the package substrate, the semiconductor die, and the bond wire.

9. The semiconductor package of claim 8, wherein the dielectric layer comprises silicon dioxide.

10. The semiconductor package of claim 8, wherein a distance between the trench and a bottom surface of the contact pad is less than 10 μm.

11. The semiconductor package of claim 8, wherein a width of the trench is less than 10 μm.

12. The semiconductor package of claim 8, wherein the trench fully surrounds the contact pad on the top surface of the BEOL layer.

13. The semiconductor package of claim 8, wherein the semiconductor die further comprises a titanium tungsten layer between the contact pad and the dielectric layer.

14. The semiconductor package of claim 8, wherein the contact pad comprises copper.

15. A method of forming a semiconductor package, comprising:
attaching a semiconductor die to a package substrate, the semiconductor die comprising a semiconductor substrate, a back-end-of-line (BEOL) layer on the semiconductor substrate, the BEOL layer including a dielectric layer on a top surface, and a contact pad on the dielectric layer, wherein the dielectric layer comprises a trench and the trench locates along a periphery of the contact pad;
attaching a bond wire to the contact pad and the package substrate; and
covering the semiconductor die, the package substrate, and the bond wire with a mold compound.

16. The method of claim 15, wherein the trench is formed by a laser grooving or an etching process.

17. The method of claim 15, wherein the dielectric layer comprises silicon dioxide.

18. The method of claim 15, wherein a distance between the trench and a bottom surface of the contact pad is less than 10 μm.

19. The method of claim 15, wherein a width of the trench is less than 10 μm.

20. The method of claim 15, wherein the trench fully surrounds the contact pad on the top surface of the BEOL layer.
